(19) United States
(12) Patent Application Publication
(10) Pub. No.: US 2026/0358435 A1
(43) Pub. Date: Nov. 12, 2026

(54) REACTIVE POWER PREDICTION METHOD AND APPARATUS FOR GENERATOR UNIT LEADING PHASE OPERATION TEST, AND COMPUTER DEVICE

(71) Applicants: CSG POWER GENERATION CO., LTD. MAINTENANCE AND TEST COMPANY, Guangzhou (CN); GUANGZHOU QIMING SHUZHI ENERGY TECHNOLOGY CO., LTD., Guangzhou (CN)

(72) Inventors: Yu GONG, Guangzhou (CN); Wenbin YAN, Guangzhou (CN); Lei ZHANG, Guangzhou (CN); Qing LI, Guangzhou (CN); Chuangjia CHEN, Guangzhou (CN); Yuji ZHANG, Guangzhou (CN); Xiongwei YANG, Guangzhou (CN); Qiang CHEN, Guangzhou (CN); Hang NIE, Guangzhou (CN); Tao YU, Guangzhou (CN); Xiaoliang LI, Guangzhou (CN); Xiao LIANG, Guangzhou (CN); Xiangwei HUANG, Guangzhou (CN); Sijie WANG, Guangzhou (CN)

(73) Assignees: CSG POWER GENERATION CO., LTD. MAINTENANCE AND TEST COMPANY, Guangzhou (CN); GUANGZHOU QIMING SHUZHI ENERGY TECHNOLOGY CO., LTD., Guangzhou (CN)

(21) Appl. No.: 19/489,301

(22) PCT Filed: Nov. 27, 2024
(86) PCT No.: PCT/CN2024/134901

§ 371 Date: Dec. 2, 2025

(30) Foreign Application Priority Data
Nov. 28, 2023 (CN) 202311598202.6

(51) Int. Cl. G01R 31/40

(52) U.S. Cl. CPC G01R 31/40

(57) ABSTRACT

A reactive power prediction method and device for a generator unit leading-phase test, a computer apparatus, a storage medium, and a computer program product are disclosed. The method includes: obtaining, in response to a reactive power prediction request for a to-be-analyzed generator unit, a unit type of the to-be-analyzed generator unit; querying a correspondence relationship between unit types and reactive power prediction models based on the unit type of the to-be-analyzed generator unit, to obtain a target reactive power prediction model corresponding to the to-be-analyzed generator unit; and obtaining key unit data for the to-be-analyzed generator unit, and inputting the key unit data into the target reactive power prediction model, to obtain reactive power boundary values of the to-be-analyzed generator unit.

### CROSS-REFERENCE TO RELATED APPLICATIONS

The present application is the national phase under 35 U.S.C. § 371 of PCT international application No. PCT/CN2024/134901, which has an international filing date of Nov. 27, 2024 and claims priority to Chinese patent application No. 202311598202.6, filed on Nov. 28, 2023, and entitled “REACTIVE POWER PREDICTION METHOD AND APPARATUS FOR GENERATOR UNIT LEADING-PHASE TEST, AND COMPUTER DEVICE”. The contents of the above identified PCT international application and Chinese patent application are hereby incorporated in their entireties by reference for all purposes.

### TECHNICAL FIELD

The present disclosure relates to a reactive power prediction method and device for a generator unit leading-phase test, a computer apparatus, a storage medium, and a computer program product.

### BACKGROUND

In a power grid system, during the leading-phase test of a generator unit, measuring the reactive power boundary values of a generator unit leading-phase test is crucial for protecting the generator unit.

In conventional technologies, when measuring the reactive power boundary values of the generator unit leading-phase test, manual observation of key unit data is mainly adopted. When abnormal values appear in the key unit data, the reactive power boundary values of the generator unit are determined through measurement; however, this method is labor-intensive and time-consuming, resulting in low measurement efficiency of the reactive power boundary values of the generator unit.

### SUMMARY

According to various embodiments of the present disclosure, a reactive power prediction method and device for a generator unit leading-phase test, a computer apparatus, a storage medium, and a computer program product are provided.

A reactive power prediction method for a generator unit leading-phase test includes:
obtaining, in response to a reactive power prediction request for a to-be-analyzed generator unit, a unit type of the to-be-analyzed generator unit;
querying a correspondence relationship between unit types and reactive power prediction models based on the unit type of the to-be-analyzed generator unit, to obtain a target reactive power prediction model corresponding to the to-be-analyzed generator unit; and
obtaining key unit data for the to-be-analyzed generator unit, and inputting the key unit data into the target reactive power prediction model, to obtain reactive power boundary values of the to-be-analyzed generator unit.

A reactive power prediction device for a generator unit leading-phase test includes:
a type determination module configured to obtain a unit type of the to-be-analyzed generator unit in response to a reactive power prediction request for a to-be-analyzed generator unit;
a model determination module configured to query a correspondence relationship between unit types and reactive power prediction models based on the unit type of the to-be-analyzed generator unit, to obtain a target reactive power prediction model corresponding to the to-be-analyzed generator unit; and
a boundary prediction module configured to obtain key unit data for the to-be-analyzed generator unit, and input the key unit data into the target reactive power prediction model, to obtain reactive power boundary values of the to-be-analyzed generator unit.

A computer apparatus includes a memory and one or more processors. The memory stores computer-readable instructions. When the computer-readable instructions are executed by the processors, the steps of the reactive power prediction method for the generator unit leading-phase test provided in any embodiment of the present disclosure are implemented.

One or more non-transitory computer-readable storage media storing computer-readable instructions, when the computer-readable instructions are executed by one or more processors, cause the one or more processors to implement the steps of the reactive power prediction method for the generator unit leading-phase test provided in any embodiment of the present disclosure.

A computer program product includes computer-readable instructions. When the computer-readable instructions are executed by a processor, the steps of the reactive power prediction method for a generator unit leading-phase test provided in any embodiment of the present disclosure are implemented.

Details of one or more embodiments of the present disclosure are set forth in the accompanying drawings and the description below. Other features, objects, and advantages of the present disclosure will become apparent from the description, the accompanying drawings, and the claims.

### BRIEF DESCRIPTION OF THE DRAWINGS

To more clearly illustrate the technical solutions in the embodiments of the present disclosure or the conventional technologies, the following briefly introduces the accompanying drawings required for describing the embodiments or the conventional technologies. Apparently, the accompanying drawings in the following description are only embodiments of the present disclosure. For those of ordinary skill in the art, other accompanying drawings can be obtained according to the disclosed accompanying drawings without creative efforts.

FIG. 1 is a schematic diagram illustrating an application environment of a reactive power prediction method for a generator unit leading-phase test according to one or more embodiments.

FIG. 2 is a schematic flowchart illustrating a reactive power prediction method for a generator unit leading-phase test according to one or more embodiments.

FIG. 3 is a schematic flowchart illustrating steps of constructing a correspondence relationship between unit types and reactive power prediction models according to one or more embodiments.

FIG. 4 is a schematic flowchart illustrating steps of obtaining a plurality of trained reactive power prediction models corresponding to each type of sample generator unit according to one or more embodiments.

FIG. 5 is a schematic flowchart illustrating steps of training a plurality of trained reactive power prediction models corresponding to each type of sample generator unit according to one or more embodiments.

FIG. 6 is a schematic flowchart illustrating steps of determining the prediction accuracy of a plurality of trained reactive power prediction models corresponding to each type of sample generator unit according to one or more embodiments.

FIG. 7 is a schematic flowchart illustrating steps of obtaining reactive power boundary values of a to-be-analyzed generator unit according to one or more embodiments.

FIG. 8 is a schematic flowchart illustrating another reactive power prediction method for a generator unit leading-phase test according to one or more embodiments.

FIG. 9 is a block diagram illustrating a reactive power prediction device for a generator unit leading-phase test according to one or more embodiments.

FIG. 10 is a block diagram illustrating a computer apparatus according to one or more embodiments.

### DETAILED DESCRIPTION OF THE EMBODIMENTS

To make the technical solutions and advantages of the present disclosure clearer, the present disclosure will be further described in detail below with reference to the accompanying drawings and embodiments. It should be understood that the specific embodiments described herein are only used to explain the present disclosure, and are not used to limit the present disclosure.

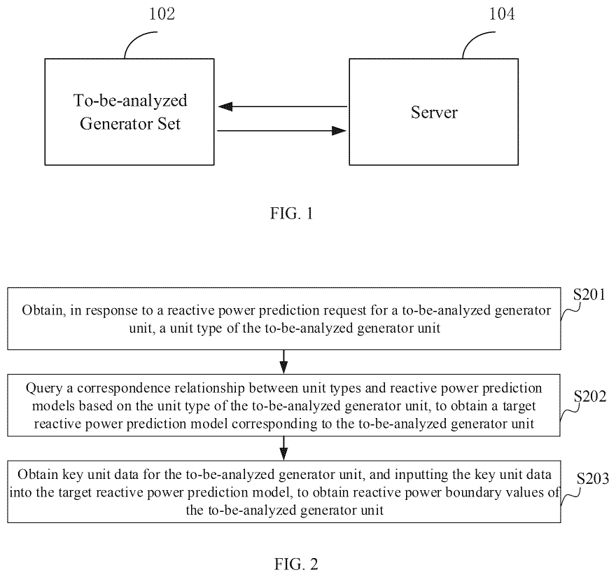

The reactive power prediction method for the generator unit leading-phase test provided in the embodiments of the present disclosure can be applied to the application environment shown in FIG. 1. The to-be-analyzed generator unit 102 communicates with the server 104 through a network. The server 104 obtains a unit type of the to-be-analyzed generator unit 102 in response to a reactive power prediction request for the to-be-analyzed generator unit 102, queries a correspondence relationship between unit types and reactive power prediction models based on the unit type of the to-be-analyzed generator unit 102 to obtain a target reactive power prediction model corresponding to the to-be-analyzed generator unit 102. The server 104 obtains key unit data for the to-be-analyzed generator unit 102, and inputs the key unit data into the target reactive power prediction model, to obtain the reactive power boundary values of the to-be-analyzed generator unit 102. The to-be-analyzed generator unit 102 refers to a generator unit for which the reactive power boundary values need to be measured, and the server 104 can be an independent server or a server cluster including multiple servers.

In an embodiment, as shown in FIG. 2, a reactive power prediction method for a generator unit leading-phase test is provided. Taking the method applied to the server in FIG. 1 as an example, it includes the following steps S201 to S203.

In step S201, in response to a reactive power prediction request for a to-be-analyzed generator unit, a unit type of the to-be-analyzed generator unit is obtained.

The to-be-analyzed generator unit refers to a generator unit for which the reactive power boundary values need to be measured.

The reactive power prediction request is request information for measuring the reactive power boundary values of the to-be-analyzed generator unit.

The unit type of the to-be-analyzed generator unit refers to a type to which the to-be-analyzed generator unit belongs.

Exemplarily, the server first obtains the generator unit identifier (such as a model of the generator unit) of the to-be-analyzed generator unit, in response to a reactive power prediction request for the to-be-analyzed generator unit, and then obtains the unit type corresponding to the generator unit identifier from a database as the unit type of the to-be-analyzed generator unit.

In step S202, a correspondence relationship between the unit types and the reactive power prediction models is queried based on the unit type of the to-be-analyzed generator unit, to obtain a target reactive power prediction model corresponding to the to-be-analyzed generator unit.

The reactive power prediction models refer to network models that can obtain the reactive power boundary values of the generator unit by using the key unit data of the generator unit. In practical scenarios, the reactive power prediction models include but are not limited to a convolutional network model, a machine learning model, or a deep learning model.

The correspondence relationship between the unit types and the reactive power prediction models refers to information on association between the unit types and the reactive power prediction models. For example, type A generator units correspond to reactive power prediction model a, type B generator units correspond to reactive power prediction model b, and type C generator units correspond to reactive power prediction model c.

The target reactive power prediction model corresponding to the to-be-analyzed generator unit refers to a reactive power prediction model adapted to the to-be-analyzed generator unit.

Exemplarily, the server queries the correspondence relationship between the unit types and the reactive power prediction models based on the unit type of the to-be-analyzed generator unit, to obtain the reactive power prediction models corresponding to the unit type of the to-be-analyzed generator unit as the target reactive power prediction model corresponding to the to-be-analyzed generator unit.

In step S203, key unit data for the to-be-analyzed generator unit is obtained, and the key unit data is input into the target reactive power prediction model, to obtain reactive power boundary values of the to-be-analyzed generator unit.

The key unit data refers to unit data boundary values of the to-be-analyzed generator unit, such as voltage boundary values, current boundary values, generator rated speed boundary values, open-circuit transient time constant boundary values, etc. It should be noted that the key unit data may also include other data, which can be adjusted according to actual conditions, and the specific content is not limited in the present disclosure.

The reactive power boundary values refer to boundary values of the reactive power of the to-be-analyzed generator unit. In practical scenarios, the reactive power boundary values include upper reactive power boundary values and lower reactive power boundary values.

Exemplarily, the server obtains key unit data for the to-be-analyzed generator unit, inputs each piece of sub-key unit data of the key unit data into the target reactive power prediction model corresponding to the to-be-analyzed generator unit, determines a weight corresponding to each piece of sub-key unit data through the target reactive power prediction model, splices each piece of sub-key unit data based on the weight to obtain spliced data, then predicts the spliced data to obtain the reactive power boundary values corresponding to the spliced data, and finally uses the reactive power boundary values as reactive power boundary values of the to-be-analyzed generator unit.

Further, the server obtains key unit data for the to-be-analyzed generator unit, inputs each piece of sub-key unit data of the key unit data into the target reactive power prediction model corresponding to the to-be-analyzed generator unit, predicts each piece of sub-key unit data through the target reactive power prediction model to obtain the prediction probabilities under each predetermined reactive power boundary value, and selects predetermined reactive power boundary values with the highest prediction probability from the predetermined reactive power boundary values as the reactive power boundary values of the to-be-analyzed generator unit.

In the above reactive power prediction method for a generator unit leading-phase test, first, in response to a reactive power prediction request for the to-be-analyzed generator unit, the unit type of the to-be-analyzed generator unit is obtained. Then the correspondence relationship between the unit types and the reactive power prediction models is queried based on the unit type of the to-be-analyzed generator unit, to obtain a target reactive power prediction model corresponding to the to-be-analyzed generator unit. Then key unit data for the to-be-analyzed generator unit is obtained. Finally, the key unit data is input into the target reactive power prediction model to obtain the reactive power boundary values of the to-be-analyzed generator unit. In this way, when measuring the reactive power boundary values of the generator unit leading-phase test, a corresponding reactive power prediction model is selected for different unit types of generator units, which can avoid the problem of low adaptability of a single model caused by differences between generator units of different unit types. Moreover, the method can automatically complete the measurement of the reactive power boundary values of the generator unit leading-phase test without manual intervention, avoiding the problem of consuming a large amount of manpower and time due to manual observation, which is conducive to reducing the labor cost and time cost required for measuring the reactive power boundary values of the generator unit, thereby improving the measurement efficiency of the reactive power boundary values of the generator unit.

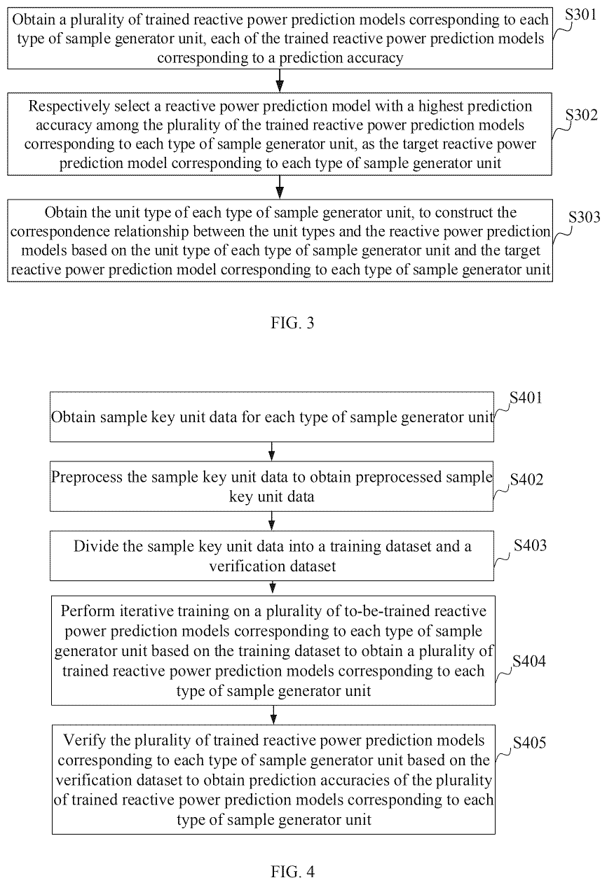

In an exemplary embodiment, as shown in FIG. 3, the reactive power prediction method for the generator unit leading-phase test provided by the present disclosure further includes steps for constructing the correspondence relationship between unit types and reactive power prediction models, specifically including the following steps S301 to S303.

In step S301, a plurality of trained reactive power prediction models corresponding to each type of sample generator unit are obtained. Each of the trained reactive power prediction models corresponds to a prediction accuracy.

In step S302, a reactive power prediction model with a highest prediction accuracy is respectively selected among the plurality of trained reactive power prediction models corresponding to each type of sample generator unit, as the target reactive power prediction model corresponding to each type of sample generator unit.

In step S303, the unit type of each type of sample generator unit is obtained, to construct the correspondence relationship between the unit types and the reactive power prediction models based on the unit type of each type of sample generator unit and the target reactive power prediction model corresponding to each type of sample generator unit.

The sample generator unit refers to a generator unit of a part of generators selected from the generator units for training the reactive power prediction model.

The prediction accuracy refers to an accuracy of a reactive power prediction model in predicting reactive power of the sample generator unit. For example, the higher the prediction accuracy, the more accurate the reactive power prediction of the sample generator unit by the reactive power prediction model. The lower the prediction accuracy, the less accurate the reactive power prediction of the sample generator unit by the reactive power prediction model.

The target reactive power prediction model corresponding to the sample generator unit refers to a reactive power prediction model adapted to the sample generator unit.

Exemplarily, the server obtains a plurality of trained reactive power prediction models corresponding to each type of sample generator unit, then respectively selects a reactive power prediction model with a highest prediction accuracy among the plurality of trained reactive power prediction models corresponding to each type of sample generator unit, based on the prediction accuracies of the reactive power prediction models for the reactive power of the sample generator unit, as the target reactive power prediction model corresponding to each type of sample generator unit, then obtains the unit type of each type of sample generator unit from the database, and constructs the correspondence relationship between unit types and reactive power prediction models based on the unit type of each type of sample generator unit and the target reactive power prediction model corresponding to each type of sample generator unit.

In this embodiment, by screening a plurality of trained reactive power prediction models corresponding to each type of sample generator unit and selecting the model with a highest prediction accuracy as the target reactive power prediction model, it is conducive to improving the prediction accuracy of reactive power prediction. Moreover, by pre-constructing the correspondence relationship between unit types and reactive power prediction models, it is convenient in practical applications to directly determine the reactive power prediction model corresponding to the unit type of the to-be-analyzed generator unit through the correspondence relationship between unit types and reactive power prediction models after obtaining the unit type of the to-be-analyzed generator unit, thereby improving the measurement efficiency of the reactive power boundary values of the generator unit.

In an exemplary embodiment, as shown in FIG. 4, the above step S301, obtaining the plurality of trained reactive power prediction models corresponding to each type of sample generator unit, specifically includes the following steps S401 to S405.

In step S401, sample key unit data for each type of sample generator unit is obtained.

In step S402, the sample key unit data is preprocessed to obtain preprocessed sample key unit data.

In step S403, the preprocessed sample key unit data is divided into a training dataset and a verification dataset.

In step S404, iterative training is performed on a plurality of to-be-trained reactive power prediction models corresponding to each type of sample generator unit based on the training dataset to obtain a plurality of trained reactive power prediction models corresponding to each type of sample generator unit.

In step S405, the plurality of trained reactive power prediction models corresponding to each type of sample generator unit is verified based on the verification dataset to obtain prediction accuracies of the plurality of trained reactive power prediction models corresponding to each type of sample generator unit.

The sample key unit data refers to unit data boundary values of the sample generator unit.

The training dataset refers to a subset of the sample key unit data that is configured for iterative training on the to-be-trained reactive power prediction models.

The verification dataset refers to a subset of the sample key unit data that is configured for verifying the trained reactive power prediction models.

Exemplarily, the server obtains sample key unit data for each type of sample generator unit, then preprocesses the sample key unit data to obtain preprocessed sample key unit data, and then divides the preprocessed sample key unit data into a training dataset and a verification dataset. The server performs iterative training on a plurality of to-be-trained reactive power prediction models corresponding to each type of sample generator unit based on the training dataset to obtain a plurality of trained reactive power prediction models corresponding to each type of sample generator unit. Finally, the server verifies the plurality of trained reactive power prediction models corresponding to each type of sample generator unit based on the verification dataset to obtain the prediction accuracies of the plurality of trained reactive power prediction models corresponding to each type of sample generator unit.

For example, the server respectively inputs data such as voltage boundary values, current boundary values, generator rated speed boundary values, and open-circuit transient time constant boundary values into the to-be-trained reactive power prediction models based on the training dataset, determines weights of data such as voltage boundary values, current boundary values, generator rated speed boundary values, and open-circuit transient time constant boundary values through the to-be-trained reactive power prediction models, splices data such as voltage boundary values, current boundary values, generator rated speed boundary values, and open-circuit transient time constant boundary values based on the weights to obtain spliced data, predicts the spliced data to obtain corresponding predicted reactive power boundary values, determines a loss value based on differences between the predicted reactive power boundary values and the actual reactive power boundary values, and performs iterative training on the to-be-trained reactive power prediction models based on the loss value to obtain the trained reactive power prediction models.

In this embodiment, by dividing the preprocessed sample key unit data into the training dataset and the verification dataset, the to-be-trained reactive power prediction models are iteratively trained based on the training dataset. Then, the plurality of trained reactive power prediction models corresponding to each type of sample generator unit are verified based on the verification dataset to obtain the prediction accuracies corresponding to the reactive power prediction models, so that a reactive power prediction model with a highest prediction accuracy can be used as the reactive power prediction model adapted to the sample generator unit in the subsequent process. Moreover, the entire process does not require manual processing, thereby improving the construction efficiency of the correspondence relationship between unit types and reactive power prediction models.

In an exemplary embodiment, as shown in FIG. 5, the above step S404, performing iterative training on the plurality of to-be-trained reactive power prediction models corresponding to each type of sample generator unit based on the training dataset to obtain the plurality of trained reactive power prediction models corresponding to each type of sample generator unit, specifically includes the following steps S501 to S503.

In step S501, first sample key unit data in the training dataset is respectively input into the plurality of to-be-trained reactive power prediction models corresponding to each type of sample generator unit to obtain predicted generator reactive powers, which are output by each of the to-be-trained reactive power prediction models and correspond to the first sample key unit data.

In step S502, actual generator unit reactive powers corresponding to the first sample key unit data are obtained, and iterative training is performed on each of the to-be-trained reactive power prediction models based on differences between the predicted generator reactive powers, which are output by each of the to-be-trained reactive power prediction models and correspond to the first sample key unit data, and the actual generator unit reactive powers, until a predetermined end condition is met.

In step S503, each of the trained reactive power prediction models that meets the predetermined end condition is used as one of the plurality of trained reactive power prediction models corresponding to each type of sample generator unit.

The first sample key unit data refers to unit data boundary values of the sample generator unit in the training dataset.

The predicted generator unit reactive powers corresponding to the first sample key unit data refer to predicted values of the reactive power boundary values of the sample generator unit based on the first sample key unit data.

The actual generator unit reactive powers corresponding to the first sample key unit data refer to actual values of the reactive power boundary values of the sample generator unit corresponding to the first sample key unit data.

The predetermined end condition refers to a predetermined training end condition, which can be specifically determined based on actual conditions.

Exemplarily, the server respectively inputs the first sample key unit data in the training dataset into a plurality of to-be-trained reactive power prediction models corresponding to each type of sample generator unit, predicts the reactive power boundary values of the sample generator unit through the reactive power prediction models to obtain the predicted generator reactive powers, which are output by each of the to-be-trained reactive power prediction models and correspond to the first sample key unit data. Then, the server obtains the actual generator unit reactive powers corresponding to the first sample key unit data, performs iterative training on each of the to-be-trained reactive power prediction models based on differences between the predicted generator reactive powers, which are output by each of the to-be-trained reactive power prediction models and correspond to the first sample key unit data, and the actual generator unit reactive powers, and then judges iteratively trained reactive power prediction models according to the predetermined end condition. If an iteratively trained reactive power prediction model does not meet the predetermined end condition, the iteratively trained reactive power prediction model is used as the to-be-trained reactive power prediction model, and the process jumps to the step of respectively inputting the first sample key unit data in the training dataset into the plurality of to-be-trained reactive power prediction models corresponding to each type of sample generator unit to obtain the predicted generator reactive powers, which are output by each of the to-be-trained reactive power prediction models and correspond to the first sample key unit data, until the predetermined end condition is met. Finally, the server uses each of the trained reactive power prediction models that meets the predetermined end condition as one of the plurality of trained reactive power prediction models corresponding to each type of sample generator unit.

For example, the server respectively inputs the first sample key unit data in the training dataset into the plurality of to-be-trained reactive power prediction models corresponding to each type of sample generator unit to obtain the predicted generator reactive powers, which are output by each of the to-be-trained reactive power prediction models and correspond to the first sample key unit data. The server obtains the actual generator unit reactive powers corresponding to the first sample key unit data, to determine a target loss value based on differences between the predicted generator reactive powers, which are output by each of the to-be-trained reactive power prediction models and correspond to the first sample key unit data, and the actual generator unit reactive powers. The server adjusts model parameters of the reactive power prediction models based on the target loss value, and performs retraining on the reactive power prediction models with adjusted model parameters until the target loss value obtained by the trained reactive power prediction models is less than the target threshold, then stops the training, and uses the trained reactive power prediction models as one of the plurality of trained reactive power prediction models corresponding to each type of sample generator unit.

In this embodiment, by pre-training the reactive power prediction models, it is convenient in practical applications to predict the reactive power boundary values of the generator unit after determining a corresponding target reactive power prediction model and obtaining the key unit data of the generator unit. Moreover, the reactive power prediction models receive new data in each iteration, perform internal improvement and optimization of the models, which is conducive to more effective prediction, thereby improving the measurement efficiency of the reactive power boundary values of the generator unit.

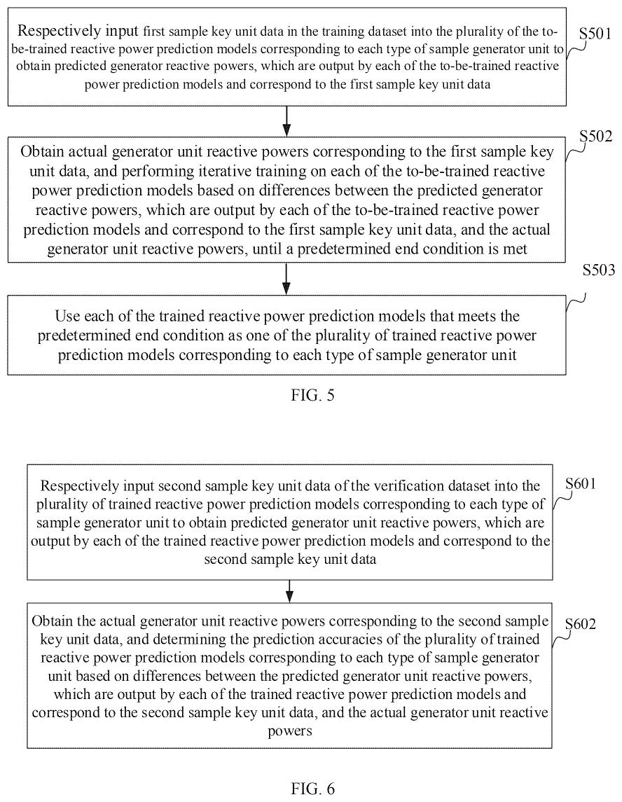

In an exemplary embodiment, as shown in FIG. 6, the above step S405, verifying the plurality of trained reactive power prediction models corresponding to each type of sample generator unit based on the verification dataset to obtain prediction accuracies of the plurality of trained reactive power prediction models corresponding to each type of sample generator unit, specifically includes the following steps S601 to S602.

In step S601, second sample key unit data in the verification dataset is respectively input into the plurality of trained reactive power prediction models corresponding to each type of sample generator unit to obtain predicted generator unit reactive powers, which are output by each of the trained reactive power prediction models and correspond to the second sample key unit data.

In step S602, actual generator unit reactive powers corresponding to the second sample key unit data are obtained, and the prediction accuracies of the plurality of trained reactive power prediction models corresponding to each type of sample generator unit are determined based on differences between the predicted generator unit reactive powers, which are output by each of the trained reactive power prediction models and correspond to the second sample key unit data, and the actual generator unit reactive powers.

The second sample key unit data refers to unit data boundary values of the sample generator unit in the verification dataset.

The predicted generator unit reactive powers corresponding to the second sample key unit data refer to predicted values of the reactive power boundary values of the sample generator unit based on the second sample key unit data.

The actual generator unit reactive powers corresponding to the second sample key unit data refer to actual values of the reactive power boundary values of the sample generator unit corresponding to the second sample key unit data.

Exemplarily, the server respectively inputs the second sample key unit data in the verification dataset into the plurality of trained reactive power prediction models corresponding to each type of sample generator unit, predicts the reactive power boundary values of the sample generator unit through the reactive power prediction models to obtain the predicted generator unit reactive powers, which are output by each of the trained reactive power prediction models and correspond to the second sample key unit data. Then, the server obtains the actual generator unit reactive powers corresponding to the second sample key unit data, compares the predicted generator unit reactive powers with the actual generator unit reactive powers to obtain differences between the predicted generator unit reactive powers, which are output by each of the trained reactive power prediction models and correspond to the second sample key unit data, and and the actual generator unit reactive powers, and then determines the prediction accuracies of the plurality of trained reactive power prediction models corresponding to each type of sample generator unit based on the difference.

For example, the server obtains the actual generator unit reactive powers corresponding to the second sample key unit data, subtracts the predicted generator unit reactive power from the actual generator unit reactive powers to obtain the differences between the predicted generator unit reactive powers, which are output by each of the trained reactive power prediction models and correspond to the second sample key unit data, and the actual generator unit reactive powers, and then divides obtained differences by actual generator unit reactive powers to obtain corresponding ratios, which are used as the prediction accuracies of the plurality of trained reactive power prediction models corresponding to each type of sample generator unit.

In this embodiment, the second sample key unit data in the verification dataset is input into the plurality of trained reactive power prediction models corresponding to each type of sample generator unit, and the prediction accuracies of the plurality of trained reactive power prediction models corresponding to each type of sample generator unit are determined based on predicted values and actual values of the generator unit reactive powers, which is conducive to representing the accuracies of the reactive power prediction models in predicting the reactive power of the sample generator unit, so that the reactive power prediction model with a highest prediction accuracy can be used as a reactive power prediction model adapted to the sample generator unit in the subsequent process. Moreover, the entire process does not require manual processing, thereby improving the construction efficiency of the correspondence relationship between unit types and reactive power prediction models.

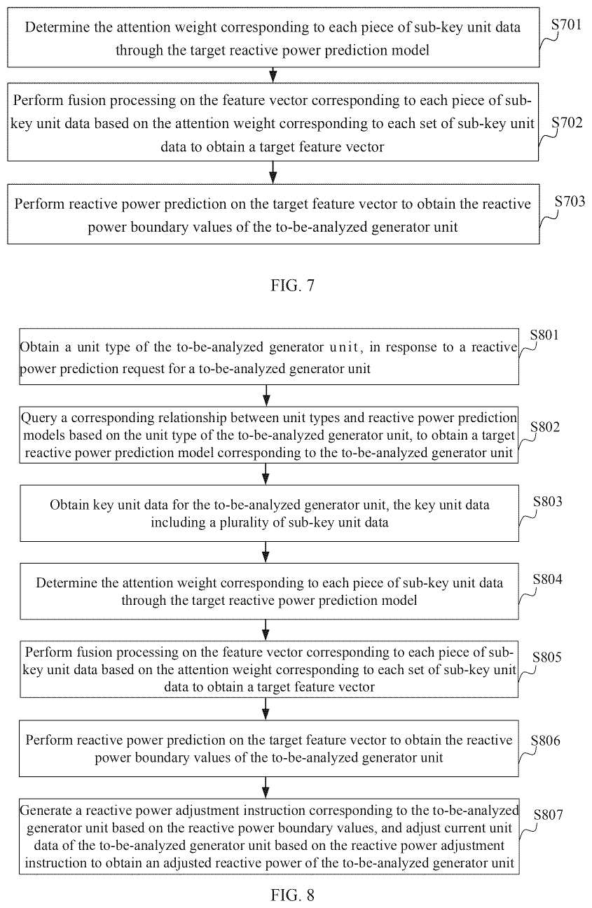

In an exemplary embodiment, as shown in FIG. 7, the above step S203, the key unit data includes a plurality of pieces of sub-key unit data. Inputting the plurality of pieces of key unit data into the target reactive power prediction model to obtain the reactive power boundary values of the to-be-analyzed generator unit, specifically includes the following steps S701 to S703.

In step S701, the attention weight corresponding to each piece of sub-key unit data is determined through the target reactive power prediction model.

In step S702, fusion processing is performed on the feature vector corresponding to each piece of sub-key unit data based on the attention weight corresponding to each piece of sub-key unit data to obtain a target feature vector.

In step S703, reactive power prediction is performed on the target feature vector to obtain the reactive power boundary values of the to-be-analyzed generator unit.

The sub-key unit data refers to different types of unit data of the key unit data.

The attention weight corresponding to the sub-key unit data refers to the importance of the sub-key unit data, which is generally represented by the percentage.

The feature vector corresponding to the sub-key unit data refers to the representation vector corresponding to the sub-key unit data feature. For example, (1, 2, 3), (2, 3, 4), etc.

Fusion processing refers to performing calculation processing on each piece of sub-key unit data and its corresponding attention weight, including but not limited to weighted processing.

The target feature vector refers to a feature vector obtained by performing fusion processing on the feature vector corresponding to each piece of sub-key unit data.

Exemplarily, the server performs feature mapping on each piece of sub-key unit data based on the features of the sub-key unit data to obtain the corresponding feature vector. For example, the server performs feature mapping processing on each piece of sub-key unit data through a feature mapping algorithm (such as a word vector algorithm, a one-hot encoding algorithm, etc.) to obtain the corresponding feature vector. Then, the server inputs the feature vector corresponding to each piece of sub-key unit data into the target reactive power prediction model, determines the attention weight corresponding to each piece of sub-key unit data through the target reactive power prediction model, then performs weighted summation processing on the feature vector corresponding to each piece of sub-key unit data, based on the attention weight corresponding to each piece of sub-key unit data, to obtain a corresponding processing result, and confirms the processing result as the target feature vector. Finally, the server performs reactive power prediction on the target feature vector to obtain the reactive power boundary values corresponding to the target feature vector, and uses the reactive power boundary values as the reactive power boundary values of the to-be-analyzed generator unit.

In this embodiment, the server determines the attention weight corresponding to each piece of sub-key unit data through the target reactive power prediction model, then performs fusion processing on the feature vector corresponding to each piece of sub-key unit data, based on the attention weight corresponding to each piece of sub-key unit data, to obtain a target feature vector, and then performs reactive power prediction on the target feature vector to obtain the reactive power boundary values of the to-be-analyzed generator unit. In this way, performing fusion processing on the feature vector corresponding to each piece of sub-key unit data, based on the attention weight corresponding to each piece of sub-key unit data, can perform fusion to different degrees based on the importance of the sub-key unit data, reduce data redundancy, which is conducive to improving the processing efficiency of the sub-key unit data, thereby improving the measurement efficiency of the reactive power boundary values of the generator unit.

In an exemplary embodiment, after the above step S203, inputting the key unit data into the target reactive power prediction model to obtain the reactive power boundary values of the to-be-analyzed generator unit, the method further includes the following steps: generating a reactive power adjustment instruction corresponding to the to-be-analyzed generator unit based on the reactive power boundary values, and adjusting current unit data for the to-be-analyzed generator unit based on the reactive power adjustment instruction to obtain an adjusted reactive power of the to-be-analyzed generator unit.

The reactive power adjustment instruction refers to an instruction for adjusting the unit data corresponding to the reactive power of the to-be-analyzed generator unit.

The current unit data refers to real-time unit data for the to-be-analyzed generator unit, such as voltage, current, generator rated speed, open-circuit transient time constant, etc.

Exemplarily, the server generates a reactive power adjustment instruction corresponding to the to-be-analyzed generator unit based on the reactive power boundary values, then adjusts current unit data for the to-be-analyzed generator unit based on the reactive power adjustment instruction to obtain adjusted unit data, and uses the reactive power corresponding to the adjusted unit data as adjusted reactive power of the to-be-analyzed generator unit.

For example, assuming that the current unit data correspond to the current reactive power (such as 50 W), the server adjusts current unit data for the to-be-analyzed generator unit based on obtained reactive power boundary values of the to-be-analyzed generator unit (such as 100 W). After adjusting the current unit data, the adjusted unit data corresponds to the adjusted reactive power (such as 70 W), and adjustment can be continued based on a current adjustment step size. When approaching the reactive power boundary values (such as 90 W), the adjustment step size is reduced to protect the safety of the generator unit.

In this embodiment, first, a reactive power adjustment instruction corresponding to the to-be-analyzed generator unit is generated based on the reactive power boundary values, and then the current unit data for the to-be-analyzed generator unit is adjusted based on the reactive power adjustment instruction to obtain the adjusted reactive power of the to-be-analyzed generator unit. In this way, when adjusting the current unit data, damage to the generator unit caused by an excessively large adjustment step size can be avoided, which is conducive to improving the safety of the generator unit.

In an exemplary embodiment, as shown in FIG. 8, another reactive power prediction method for a generator unit leading-phase test is provided. Taking the method applied to a server as an example, it includes the following steps S801 to S807.

In step S801, a unit type of the to-be-analyzed generator unit is obtained, in response to a reactive power prediction request for a to-be-analyzed generator unit.

In step S802, a correspondence relationship between unit types and reactive power prediction models is queried based on the unit type of the to-be-analyzed generator unit, to obtain a target reactive power prediction model corresponding to the to-be-analyzed generator unit.

In step S803, key unit data for the to-be-analyzed generator unit is obtained. The key unit data includes a plurality of sub-key unit data.

In step S804, the attention weight corresponding to each piece of sub-key unit data is determined through the target reactive power prediction model.

In step S805, fusion processing is performed on the feature vector corresponding to each piece of sub-key unit data based on the attention weight corresponding to each piece of sub-key unit data to obtain a target feature vector.

In step S806, reactive power prediction is performed on the target feature vector to obtain the reactive power boundary values of the to-be-analyzed generator unit.

In step S807, a reactive power adjustment instruction corresponding to the to-be-analyzed generator unit is generated based on the reactive power boundary values. Current unit data for the to-be-analyzed generator unit is adjusted based on the reactive power adjustment instruction to obtain an adjusted reactive power of the to-be-analyzed generator unit.

In the above reactive power prediction method for a generator unit leading-phase test, first, in response to a reactive power prediction request for the to-be-analyzed generator unit, the unit type of the to-be-analyzed generator unit is obtained. Then the correspondence relationship between the unit types and the reactive power prediction models is queried based on the unit type of the to-be-analyzed generator unit, to obtain a target reactive power prediction model corresponding to the to-be-analyzed generator unit. Then key unit data for the to-be-analyzed generator unit is obtained. Finally, the key unit data is input into the target reactive power prediction model to obtain the reactive power boundary values of the to-be-analyzed generator unit. In this way, when measuring the reactive power boundary values of the generator unit leading-phase test, a corresponding reactive power prediction model is selected for different unit types of generator units, which can avoid the problem of low adaptability of a single model caused by differences between generator units of different unit types. Moreover, the method can automatically complete the measurement of the reactive power boundary values of the generator unit leading-phase test without manual intervention, avoiding the problem of consuming a large amount of manpower and time due to manual observation, which is conducive to reducing the labor cost and time cost required for measuring the reactive power boundary values of the generator unit, thereby improving the measurement efficiency of the reactive power boundary values of the generator unit.

In an exemplary embodiment, to more clearly illustrate the reactive power prediction method for a generator unit leading-phase test provided in the embodiments of the present disclosure, the reactive power prediction method for a generator unit leading-phase test is specifically described below with a specific embodiment. In an embodiment, the present disclosure further provides a multi-model-based reactive power boundary prediction method for a generator unit leading-phase test. When measuring the reactive power boundary values of the generator unit leading-phase test, the correspondence relationship between the unit types of the generator units and the reactive power prediction models is queried based on a unit type of a current generator unit to determine a reactive power prediction model corresponding to the current generator unit, and current relevant boundary data of the current generator unit is processed based on the reactive power prediction model corresponding to the current generator unit to obtain predicted reactive power boundary values of the current generator unit. Specifically, it includes the following steps.
(1) A plurality of pieces of sample data for different types of generator units are collected. Each piece of sample data includes actual reactive power boundary values and a plurality of test constraint parameters.
(2) The plurality pieces of sample data are preprocessed to remove invalid data, to obtain preprocessed sample data.
(3) For each type of generator unit, the preprocessed sample data is divided into a training set and a verification set.
(4) A plurality of to-be-trained models (such as convolutional network models, machine learning models, deep learning models, etc.) are respectively trained based on the training set to obtain a plurality of trained models. For example, a plurality of test constraint parameters is input into the to-be-trained models, the weights of the plurality of test constraint parameters are determined through the to-be-trained models, the plurality of test constraint parameters are spliced based on the weights to obtain spliced data, the spliced data is predicted to obtain predicted reactive power values. A loss value is determined based on differences between the predicted reactive power values and actual reactive power values, and iterative training is performed on the to-be-trained models based on the loss value to obtain the trained models.
(5) Prediction accuracies of each of the trained models are respectively determined by using the verification set.
(6) A model with a highest prediction accuracy is selected among the plurality of trained models as a power prediction model of the corresponding generator unit, to obtain a reactive power prediction model corresponding to each generator unit, i.e., there is a correspondence relationship between the unit types of the generator units and the reactive power prediction models. For example, type A generator units correspond to model a, type B generator units correspond to model b, and type C generator units correspond to model C.
(7) In the operation and maintenance phase, the correspondence relationship between the unit types of the generator units and the reactive power prediction models is queried based on the unit type of the current generator unit to determine the reactive power prediction model corresponding to the current generator unit. Current relevant boundary data of the current generator unit are processed based on the reactive power prediction model corresponding to the current generator unit to obtain the predicted reactive power boundary values of the current generator unit. In this way, when adjusting the reactive power, the reactive power boundary values can be known in advance. For example, an initial adjustment step size is relatively large, and when approaching the reactive power boundary values, the adjustment step size becomes smaller. Alternatively, the current reactive power is calculated by using current relevant data.

In the above embodiment, when measuring the reactive power boundary values of the generator unit leading-phase test, a corresponding reactive power prediction model is selected for different unit types of generator units, which can avoid a problem of low adaptability of a single model caused by differences between generator units of different unit types. Moreover, the method can automatically complete the measurement of the reactive power boundary values of the generator unit leading-phase test without manual intervention, avoiding the problem of consuming a large amount of manpower and time due to manual observation, which is conducive to reducing the labor cost and time cost required for measuring the reactive power boundary values of the generator unit, thereby improving the measurement efficiency of the reactive power boundary values of the generator unit.

It should be understood that although the various steps in the flowcharts involved in the above embodiments are displayed in sequence according to the arrows, these steps are not necessarily executed in sequence according to the order indicated by the arrows. Unless explicitly stated herein, the execution of these steps is not strictly limited in order, and these steps can be executed in other orders. Moreover, at least part of the steps in the flowcharts involved in the above embodiments may include multiple steps or multiple stages. These steps or stages are not necessarily executed at the same time, but can be executed at different times. The execution order of these steps or stages is not necessarily sequential, but can be rotated or alternately executed with at least part of the steps or stages in other steps or other steps.

Based on the same inventive concept, the embodiment of the present disclosure also provides a reactive power prediction device for a generator unit leading-phase test for implementing the above-mentioned reactive power prediction method for a generator unit leading-phase test. The implementation scheme for solving the problem provided by the apparatus is similar to the implementation scheme recorded in the above method, so the specific limitations in one or more embodiments of the reactive power prediction device for a generator unit leading-phase test provided below can be referred to the limitations on the reactive power prediction method for a generator unit leading-phase test above, and will not be repeated here.

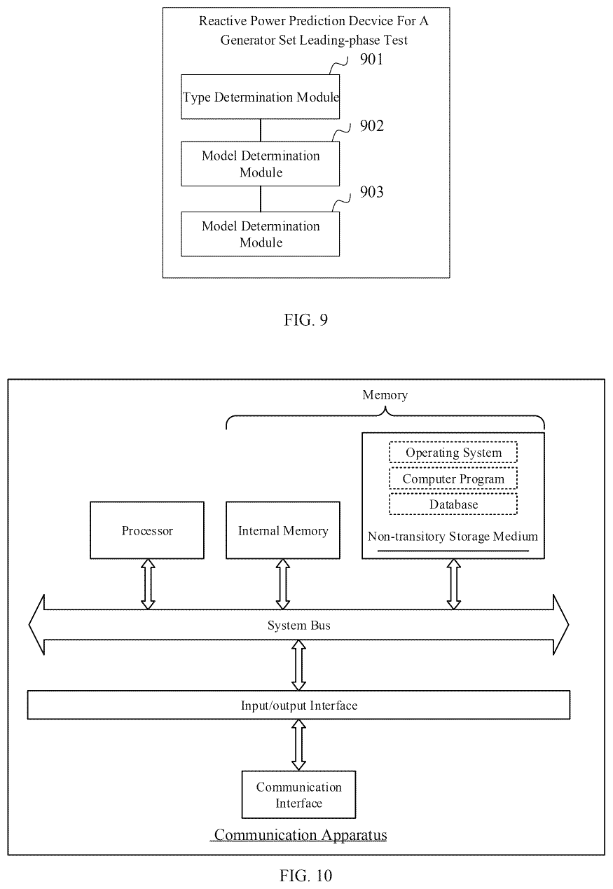

In an exemplary embodiment, as shown in FIG. 9, a reactive power prediction device for a generator unit leading-phase test is provided. The device includes: a type determination module 901, a model determination module 902, and a boundary prediction module 903.

The type determination module 901 is configured to obtain a unit type of the to-be-analyzed generator unit in response to a reactive power prediction request for a to-be-analyzed generator unit.

The model determination module 902 is configured to query a correspondence relationship between unit types and reactive power prediction models based on the unit type of the to-be-analyzed generator unit, to obtain a target reactive power prediction model corresponding to the to-be-analyzed generator unit.

The boundary prediction module 903 is configured to obtain key unit data for the to-be-analyzed generator unit, and input the key unit data into the target reactive power prediction model, to obtain reactive power boundary values of the to-be-analyzed generator unit.

In an exemplary embodiment, the reactive power prediction device for a generator unit leading-phase test further includes a relationship construction module configured to obtain the plurality of trained reactive power prediction models corresponding to each type of sample generator unit, where each of the trained reactive power prediction models corresponds to a prediction accuracy, respectively select a reactive power prediction model with a highest prediction accuracy among the plurality of trained reactive power prediction models corresponding to each type of sample generator unit, as the target reactive power prediction model corresponding to each type of sample generator unit, and obtain the unit type of each type of sample generator unit, to construct the correspondence relationship between the unit types and the reactive power prediction models based on the unit type of each type of sample generator unit and the target reactive power prediction model corresponding to each type of sample generator unit.

In an exemplary embodiment, the relationship construction module is further configured to obtain sample key unit data for each type of sample generator unit, preprocess the sample key unit data to obtain preprocessed sample key unit data, divide the preprocessed sample key unit data into a training dataset and a verification dataset, perform iterative training on a plurality of to-be-trained reactive power prediction models corresponding to each type of sample generator unit based on the training dataset to obtain a plurality of trained reactive power prediction models corresponding to each type of sample generator unit, and verify the plurality of trained reactive power prediction models corresponding to each type of sample generator unit based on the verification dataset to obtain prediction accuracies of the plurality of trained reactive power prediction models corresponding to each type of sample generator unit.

In an exemplary embodiment, the relationship construction module is further configured to respectively input first sample key unit data in the training dataset into the plurality of to-be-trained reactive power prediction models corresponding to each type of sample generator unit to obtain predicted generator reactive powers, which are output by each of the to-be-trained reactive power prediction models and correspond to the first sample key unit data, obtain actual generator unit reactive powers corresponding to the first sample key unit data, and perform iterative training on each of the to-be-trained reactive power prediction models based on differences between the predicted generator reactive powers, which are output by each of the to-be-trained reactive power prediction models and correspond to the first sample key unit data, and the actual generator unit reactive powers, until a predetermined end condition is met, and use each of the trained reactive power prediction models that meets the predetermined end condition as one of the plurality of trained reactive power prediction models corresponding to each type of sample generator unit.

In an exemplary embodiment, the relationship construction module is further configured to respectively input second sample key unit data in the verification dataset into the plurality of trained reactive power prediction models corresponding to each type of sample generator unit to obtain predicted generator unit reactive powers, which are output by each of the trained reactive power prediction models and correspond to the second sample key unit data, and obtain the actual generator unit reactive powers corresponding to the second sample key unit data, and determine the prediction accuracies of the plurality of trained reactive power prediction models corresponding to each type of sample generator unit, based on differences between the predicted generator unit reactive powers, which are output by each of the trained reactive power prediction models and correspond to the second sample key unit data, and the actual generator unit reactive powers.

In an exemplary embodiment, the boundary prediction module 903 is further configured to determine the attention weight corresponding to each piece of sub-key unit data through the target reactive power prediction model, perform fusion processing on the feature vector corresponding to each piece of sub-key unit data based on the attention weight corresponding to each piece of sub-key unit data to obtain a target feature vector; and perform reactive power prediction on the target feature vector to obtain the reactive power boundary values of the to-be-analyzed generator unit.

In an exemplary embodiment, the reactive power prediction device for a generator unit leading-phase test further includes a data adjustment module configured to generate a reactive power adjustment instruction corresponding to the to-be-analyzed generator unit based on the reactive power boundary values, and adjust current unit data for the to-be-analyzed generator unit based on the reactive power adjustment instruction to obtain an adjusted reactive power of the to-be-analyzed generator unit.

Each module in the above reactive power prediction device for a generator unit leading-phase test can be fully or partially implemented by software, hardware, or a combination thereof. Each of the above modules can be embedded in or independent of the processor of the computer apparatus in the form of hardware, or stored in the memory of the computer apparatus in the form of software, so that the processor can call and execute the operations corresponding to each of the above modules.

In an exemplary embodiment, a computer apparatus is provided. The computer apparatus can be a server, and its internal structure diagram can be as shown in FIG. 10. The computer apparatus includes a processor, a memory, an input/output interface (I/O for short), and a communication interface. The processor, the memory, and the input/output interface are connected through a system bus, and the communication interface is connected to the system bus through the input/output interface. The processor of the computer apparatus is used to provide computing and control capabilities. The memory of the computer apparatus includes a non-transitory storage medium and an internal memory. The non-transitory storage medium stores an operating system, computer-readable instructions, and a database. The internal memory provides an environment for the operation of the operating system and computer-readable instructions in the non-transitory storage medium. The database of the computer apparatus is used to store unit type data, key unit data, reactive power boundary values data, etc. The input/output interface of the computer apparatus is used for exchanging information between the processor and external equipment. The communication interface of the computer apparatus is used for communicating with an external terminal through a network connection. The computer-readable instructions are executed by the processor to implement a reactive power prediction method for a generator unit leading-phase test.

Those skilled in the art can understand that the structure shown in FIG. 10 is only a block diagram of a part of the structure related to the solution of the present disclosure, and does not constitute a limitation on a computer apparatus to which the solution of the present disclosure is applied. The specific computer apparatus may include more or fewer components than those shown in the figure, or combine some components, or have different component arrangements.

A computer apparatus includes a memory and one or more processors, where computer-readable instructions are stored in the memory, and when the computer-readable instructions are executed by the processors, the one or more processors execute the steps of the reactive power prediction method for a generator unit leading-phase test provided in any embodiment of the present disclosure.

One or more non-transitory computer-readable storage media storing computer-readable instructions, when the computer-readable instructions are executed by one or more processors, cause the one or more processors to execute the steps of the reactive power prediction method for a generator unit leading-phase test provided in any embodiment of the present disclosure.

In an embodiment, a computer program product is provided. The computer program product includes computer-readable instructions, and when the computer-readable instructions are executed by a processor, the steps of the reactive power prediction method for a generator unit leading-phase test provided in any embodiment of the present disclosure are implemented.

It should be noted that the user information (including but not limited to user equipment information, user personal information, etc.) and data (including but not limited to data used for analysis, stored data, displayed data, etc.) involved in the present disclosure are all information and data authorized by the user or fully authorized by all parties. The collection, use, and processing of relevant data need to comply with the relevant laws, regulations, and standards of relevant countries and regions.

Those of ordinary skill in the art can understand that all or part of the processes in the methods of the above embodiments can be implemented by instructing relevant hardware through computer-readable instructions. The computer-readable instructions can be stored in a non-transitory computer-readable storage medium. When the computer-readable instructions are executed, they can include the processes of the above method embodiments. Any reference to the memory, database, or other media involved in the embodiments provided in the present disclosure may include at least one of non-transitory memory and volatile memory. The non-transitory memory may include read-only memory (ROM), magnetic tape, floppy disk, flash memory, optical memory, high-density embedded non-transitory memory, resistive random access memory (ReRAM), magnetoresistive random access memory (MRAM), ferroelectric random access memory (FRAM), phase change memory (PCM), graphene memory, etc. The volatile memory may include random access memory (RAM) or external cache memory, etc. By way of illustration and not limitation, the RAM may be in various forms, such as static random access memory (SRAM) or dynamic random access memory (DRAM). The databases involved in the embodiments provided in the present disclosure may include at least one of a relational database and a non-relational database. The non-relational database may include a distributed database based on a blockchain, etc., but is not limited thereto. The processors involved in the embodiments provided in the present disclosure may be general-purpose processors, central processing units, graphics processors, digital signal processors, programmable logic devices, data processing logic devices based on quantum computing, etc., but are not limited thereto.

The technical features of the above embodiments can be combined arbitrarily. To make the description concise, not all possible combinations of the technical features in the above embodiments are described. However, as long as there is no contradiction between the combinations of these technical features, they should be regarded as the scope described in this specification.

The above embodiments only express several implementation modes of the present disclosure, and their descriptions are specific and detailed, but they cannot be understood as limitations on the scope of the patent disclosure. It should be noted that for those of ordinary skill in the art, without departing from the concept of the present disclosure, several modifications and improvements can be made, which all belong to the protection scope of the present disclosure. Therefore, the protection scope of the patent of the present disclosure should be subject to the appended claims.

1. A reactive power prediction method for a generator unit leading-phase test, the method comprising:
obtaining, in response to a reactive power prediction request for a to-be-analyzed generator unit, a unit type of the to-be-analyzed generator unit;
querying a correspondence relationship between unit types and reactive power prediction models based on the unit type of the to-be-analyzed generator unit, to obtain a target reactive power prediction model corresponding to the to-be-analyzed generator unit, the correspondence relationship being constructed based on a unit type of each type of sample generator unit and the target reactive power prediction model corresponding to each type of sample generator unit, and a target reactive power prediction model corresponding to each type of sample generator unit being a reactive power prediction model with a highest prediction accuracy among a plurality of trained reactive power prediction models corresponding to each type of sample generator unit; and
obtaining key unit data for the to-be-analyzed generator unit, and inputting the key unit data into the target reactive power prediction model, to obtain reactive power boundary values of the to-be-analyzed generator unit, the reactive power boundary values of the to-be-analyzed generator unit being determined based on an attention weight and a feature vector corresponding to each piece of sub-key unit data of the key unit data, and the attention weight corresponding to each piece of sub-key unit data of the key unit data being determined through the target reactive power prediction model.

2. The method of claim 1, wherein the correspondence relationship between the unit types and the reactive power prediction models is constructed by:
obtaining a plurality of trained reactive power prediction models corresponding to each type of sample generator unit, each of the trained reactive power prediction models corresponding to a prediction accuracy;
respectively selecting a reactive power prediction model with a highest prediction accuracy among the plurality of trained reactive power prediction models corresponding to each type of sample generator unit, as the target reactive power prediction model corresponding to each type of sample generator unit; and
obtaining the unit type of each type of sample generator unit, to construct the correspondence relationship between the unit types and the reactive power prediction models based on the unit type of each type of sample generator unit and the target reactive power prediction model corresponding to each type of sample generator unit.

3. The method of claim 2, wherein obtaining the plurality of trained reactive power prediction models corresponding to each type of sample generator unit comprises:
obtaining sample key unit data for each type of sample generator unit;
preprocessing the sample key unit data to obtain preprocessed sample key unit data;
dividing the preprocessed sample key unit data into a training dataset and a verification dataset; and
performing iterative training on a plurality of to-be-trained reactive power prediction models corresponding to each type of sample generator unit based on the training dataset, to obtain a plurality of trained reactive power prediction models corresponding to each type of sample generator unit; and
subsequent to obtaining the plurality of trained reactive power prediction models corresponding to each type of sample generator unit, the method further comprises:
verifying the plurality of trained reactive power prediction models corresponding to each type of sample generator unit based on the verification dataset to obtain prediction accuracies of the plurality of trained reactive power prediction models corresponding to each type of sample generator unit.

4. The method of claim 3, wherein performing iterative training on the plurality of to-be-trained reactive power prediction models corresponding to each type of sample generator unit based on the training dataset to obtain the plurality of trained reactive power prediction models corresponding to each type of sample generator unit comprises:
respectively inputting first sample key unit data in the training dataset into the plurality of to-be-trained reactive power prediction models corresponding to each type of sample generator unit to obtain predicted generator reactive powers, which are output by each of the to-be-trained reactive power prediction models and correspond to the first sample key unit data;
obtaining actual generator unit reactive powers corresponding to the first sample key unit data, and performing iterative training on each of the to-be-trained reactive power prediction models based on differences between the predicted generator reactive powers, which are output by each of the to-be-trained reactive power prediction models and correspond to the first sample key unit data, and the actual generator unit reactive powers, until a predetermined end condition is met; and
using each of the trained reactive power prediction models that meets the predetermined end condition as one of the plurality of trained reactive power prediction models corresponding to each type of sample generator unit.

5. The method of claim 3, wherein verifying the plurality of trained reactive power prediction models corresponding to each type of sample generator unit based on the verification dataset to obtain the prediction accuracies of the plurality of trained reactive power prediction models corresponding to each type of sample generator unit comprises:
respectively inputting second sample key unit data in the verification dataset into the plurality of trained reactive power prediction models corresponding to each type of sample generator unit to obtain predicted generator unit reactive powers, which are output by each of the trained reactive power prediction models and correspond to the second sample key unit data; and
obtaining the actual generator unit reactive powers corresponding to the second sample key unit data, and determining the prediction accuracies of the plurality of trained reactive power prediction models corresponding to each type of sample generator unit based on differences between the predicted generator unit reactive powers, which are output by each of the trained reactive power prediction models and correspond to the second sample key unit data, and the actual generator unit reactive powers.

6. The method of claim 1, wherein the key unit data comprises a plurality of pieces of sub-key unit data; and
inputting the key unit data into the target reactive power prediction model, to obtain the reactive power boundary values of the to-be-analyzed generator unit comprises:
determining the attention weight corresponding to each piece of sub-key unit data through the target reactive power prediction model;
performing fusion processing on the feature vector corresponding to each piece of sub-key unit data based on the attention weight corresponding to each piece of sub-key unit data to obtain a target feature vector; and
performing reactive power prediction on the target feature vector to obtain the reactive power boundary values of the to-be-analyzed generator unit.

7. The method of claim 1, wherein subsequent to inputting the key unit data into the target reactive power prediction model to obtain the reactive power boundary values of the to-be-analyzed generator unit, the method further comprises:
generating a reactive power adjustment instruction corresponding to the to-be-analyzed generator unit based on the reactive power boundary values; and
adjusting current unit data for the to-be-analyzed generator unit based on the reactive power adjustment instruction to obtain an adjusted reactive power of the to-be-analyzed generator unit.

8. A reactive power prediction device for a generator unit leading-phase test, the reactive power prediction device comprising:
a type determination module configured to obtain a unit type of the to-be-analyzed generator unit in response to a reactive power prediction request for a to-be-analyzed generator unit;
a model determination module configured to query a correspondence relationship between unit types and reactive power prediction models based on the unit type of the to-be-analyzed generator unit, to obtain a target reactive power prediction model corresponding to the to-be-analyzed generator unit, the correspondence relationship being constructed based on a unit type of each type of sample generator unit and the target reactive power prediction model corresponding to each type of sample generator unit, and a target reactive power prediction model corresponding to each type of sample generator unit being a reactive power prediction model with a highest prediction accuracy among a plurality of trained reactive power prediction models corresponding to each type of sample generator unit; and
a boundary prediction module configured to obtain key unit data for the to-be-analyzed generator unit, and input the key unit data into the target reactive power prediction model, to obtain reactive power boundary values of the to-be-analyzed generator unit, the reactive power boundary values of the to-be-analyzed generator unit being determined based on an attention weight and a feature vector corresponding to each piece of sub-key unit data of the key unit data, and the attention weight corresponding to each piece of sub-key unit data of the key unit data being determined through the target reactive power prediction model.

9. The reactive power prediction device of claim 8, further comprising a relationship construction module configured to: obtain the plurality of trained reactive power prediction models corresponding to each type of sample generator unit, each of the trained reactive power prediction models corresponding to a prediction accuracy; respectively select a reactive power prediction model with a highest prediction accuracy among the plurality of trained reactive power prediction models corresponding to each type of sample generator unit, as the target reactive power prediction model corresponding to each type of sample generator unit;
and obtain the unit type of each type of sample generator unit, to construct the correspondence relationship between the unit types and the reactive power prediction models based on the unit type of each type of sample generator unit and the target reactive power prediction model corresponding to each type of sample generator unit.

10. The reactive power prediction device of claim 9, wherein the relationship construction module is further configured to: obtain sample key unit data for each type of sample generator unit; preprocess the sample key unit data to obtain preprocessed sample key unit data; divide the preprocessed sample key unit data into a training dataset and a verification dataset; perform iterative training on a plurality of to-be-trained reactive power prediction models corresponding to each type of sample generator unit based on the training dataset to obtain a plurality of trained reactive power prediction models corresponding to each type of sample generator unit; and verify the plurality of trained reactive power prediction models corresponding to each type of sample generator unit based on the verification dataset to obtain prediction accuracies of the plurality of trained reactive power prediction models corresponding to each type of sample generator unit.

11. The reactive power prediction device of claim 9, wherein the relationship construction module is further configured to: respectively input first sample key unit data in the training dataset into the plurality of to-be-trained reactive power prediction models corresponding to each type of sample generator unit to obtain predicted generator reactive powers, which are output by each of the to-be-trained reactive power prediction models and correspond to the first sample key unit data; obtain actual generator unit reactive powers corresponding to the first sample key unit data, and perform iterative training on each of the to-be-trained reactive power prediction models based on differences between the predicted generator reactive powers, which are output by each of the to-be-trained reactive power prediction models and correspond to the first sample key unit data, and the actual generator unit reactive powers, until a predetermined end condition is met; and use each of the trained reactive power prediction models that meets the predetermined end condition as one of the plurality of trained reactive power prediction models corresponding to each type of sample generator unit.

12. The reactive power prediction device of claim 9, wherein the relationship construction module is further configured to: respectively input second sample key unit data in the verification dataset into the plurality of trained reactive power prediction models corresponding to each type of sample generator unit to obtain predicted generator unit reactive powers, which are output by each of the trained reactive power prediction models and correspond to the second sample key unit data; and obtain the actual generator unit reactive powers corresponding to the second sample key unit data, and determine the prediction accuracies of the plurality of trained reactive power prediction models corresponding to each type of sample generator unit based on differences between the predicted generator unit reactive powers, which are output by each of the trained reactive power prediction models and correspond to the second sample key unit data, and the actual generator unit reactive powers.

13. The reactive power prediction device of claim 8, wherein the boundary prediction module is further configured to: determine the attention weight corresponding to each piece of sub-key unit data through the target reactive power prediction model; perform fusion processing on the feature vector corresponding to each piece of sub-key unit data based on the attention weight corresponding to each piece of sub-key unit data to obtain a target feature vector; and perform reactive power prediction on the target feature vector to obtain the reactive power boundary values of the to-be-analyzed generator unit.

14. The reactive power prediction device of claim 8, further comprising a data adjustment module configured to: generate a reactive power adjustment instruction corresponding to the to-be-analyzed generator unit based on the reactive power boundary values; and adjust current unit data for the to-be-analyzed generator unit based on the reactive power adjustment instruction to obtain an adjusted reactive power of the to-be-analyzed generator unit.

15. A computer apparatus comprising a memory and one or more processors, the memory storing computer-readable instructions, wherein the computer-readable instructions, when executed by one or more processors, cause the one or more processors to implement steps of the method of claim 1.

16. One or more non-transitory computer-readable storage media storing computer-readable instructions, wherein the computer-readable instructions, when executed by one or more processors, cause the one or more processors to implement steps of the method of claim 1.

17. The method of claim 1, wherein the reactive power prediction models refer to network models configured to obtain the reactive power boundary values of a generator unit by using the key unit data of the generator unit.

18. The method of claim 1, wherein the correspondence relationship between the unit types and the reactive power prediction models refers to information on association between the unit types and the reactive power prediction models.

19. The method of claim 1, wherein the target reactive power prediction model corresponding to the to-be-analyzed generator unit refers to a reactive power prediction model adapted to the to-be-analyzed generator unit.

20. The method of claim 1, wherein the key unit data for the to-be-analyzed generator unit refers to unit data boundary values of the to-be-analyzed generator unit.
